(19) United States
(12) Patent Application Publication
(10) Pub. No.: US 2026/0032969 A1
(43) Pub. Date: Jan. 29, 2026

(54) SEMICONDUCTOR DEVICE

(71) Applicant: MICRON TECHNOLOGY, INC., BOISE, ID (US)

(72) Inventor: Keito Aoshima, Higashihiroshima (JP)

(73) Assignee: MICRON TECHNOLOGY, INC., Boise, ID (US)

(21) Appl. No.: 19/263,100

(22) Filed: Jul. 8, 2025

Related U.S. Application Data
(60) Provisional application No. 63/674,429, filed on Jul. 23, 2024.

(51) Int. Cl. H10D 30/69; H10D 84/85

(52) U.S. Cl. CPC H10D 30/792; H10D 84/85

(57) ABSTRACT

An apparatus includes: a substrate; a first region on the substrate; a second region on the substrate; at least one first transistor including a first gate structure provided in the first region; at least one second transistor including a second gate structure provided in the second region; triangular prism shaped sidewalls on both sides of the second gate structure; and a stress film covering over the first gate structure without an intervention of triangular prism shaped sidewalls.

### CROSS-REFERENCE TO RELATED APPLICATIONS

This application claims the filing benefit of U.S. Provisional Application No. 63/674,429, filed Jul. 23, 2024. This application is incorporated by reference herein in its entirety and for all purposes.

### BACKGROUND

A semiconductor device exemplified by a Dynamic Random Access Memory (DRAM) comprises an electronic circuit including many transistors. By enhancing the mobility of the transistors, the operating speed of the electronic circuit including the transistors increases, thereby improving the performance of the semiconductor device.

### BRIEF DESCRIPTION OF THE DRAWINGS

FIG. 1 is a vertical cross-sectional view showing a schematic configuration of a semiconductor device according to an embodiment. FIG. 1 is also a diagram showing a method for manufacturing a semiconductor device according to an embodiment and is a diagram showing an example of a schematic configuration at an exemplary process stage subsequent to FIG. 5.

FIG. 2 to FIG. 5 are diagrams showing the method for manufacturing a semiconductor device according to the embodiment in the order of steps and are vertical cross-sectional views showing an example of a schematic configuration at an exemplary process stage.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

A semiconductor device according to an embodiment will be described below with reference to the drawings. In the following description, a dynamic random access memory (DRAM) will be described as an example of a semiconductor device. In the description of the embodiment, common or related elements, or substantially identical elements are given the same reference signs, and description thereof will be omitted. Furthermore, in the following figures, the dimensions and dimensional ratios of respective components in the respective figures do not necessarily match the dimensions and dimensional ratios in the embodiment. In the following description, an up-down direction and a left-right direction mean directions in each figure when a semiconductor substrate is placed on a bottom side.

The semiconductor device 1 according to the embodiment is mounted, for example, on a peripheral circuit that drives memory cells of a DRAM. Furthermore, for example, the semiconductor device 1 is mounted on a logic die of a high bandwidth memory (HBM) configured by stacking a plurality of DRAM dies and the logic die for driving the DRAM dies.

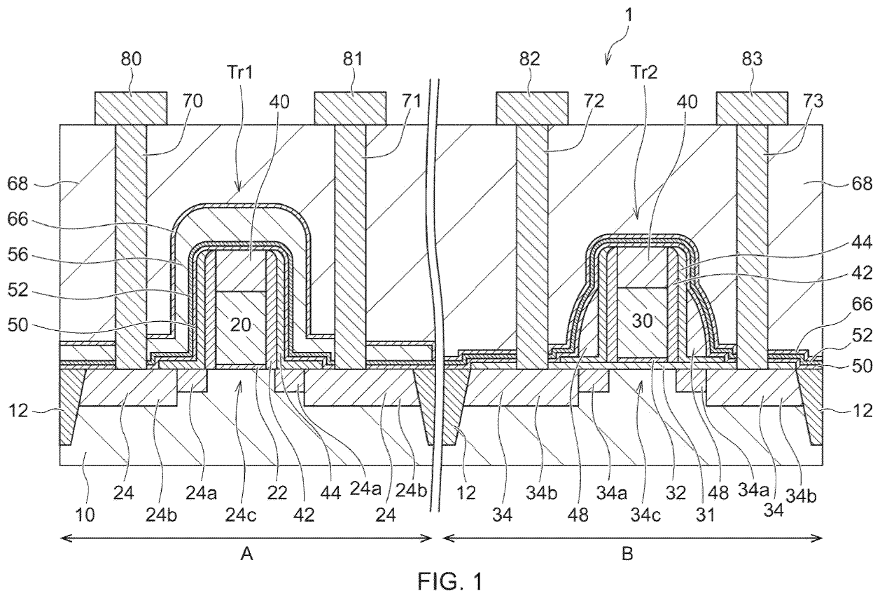

As shown in FIG. 1, the semiconductor device 1 according to the embodiment includes a plurality of first transistors Tr1 and a plurality of second transistors Tr2 arranged on a semiconductor substrate 10. FIG. 1 illustrates one first transistor Tr1 and one second transistor Tr2, but actually, a plurality of first transistors Tr1 and a plurality of second transistors Tr2 are provided. The semiconductor substrate 10 is provided with isolations 12. The semiconductor substrate 10 includes single crystal silicon. The isolations 12 are embedded in the semiconductor substrate 10, and include, for example, silicon dioxide (SiO₂). The isolation 12 has a function of electrically isolating adjacent elements from each other.

The semiconductor substrate 10 has a first region A and a second region B. The semiconductor substrate 10 in the first region A is provided with a P-well doped with impurities such as boron. The semiconductor substrate 10 in the second region B is provided with an N-well doped with impurities such as phosphorus or arsenic. The first transistor Tr1 disposed in the first region A is an N-channel metal-oxide-semiconductor field-effect transistor (MOSFET). The second transistor Tr2 disposed in the second region B is a P-channel MOSFET.

The first transistor Tr1 disposed in the first region A has a gate electrode 20 above the semiconductor substrate 10. A pair of source/drain 24 is provided on the semiconductor substrate 10 at positions where the gate electrode 20 is interposed. The second transistor Tr2 disposed in the second region B has a gate electrode 30 above the semiconductor substrate 10. A pair of source/drain 34 is provided on the semiconductor substrate 10 at positions where the gate electrode 30 is interposed. The gate electrode 20 and the gate electrode 30 include a conductive material such as titanium nitride (TiN), lanthanum (La), polysilicon (Poly Si), or tungsten (W).

The source/drain 24 includes a low concentration portion 24a and a high concentration portion 24b. The low concentration portion 24a and the high concentration portion 24b are doped with impurities such as phosphorus (P) or arsenic (As). The source/drain 24 is an N-type impurity region. The source/drain 34 includes a low concentration portion 34a and a high concentration portion 34b. The low concentration portion 34a and the high concentration portion 34b are doped with impurities such as boron (B). The source/drain 34 is a P-type impurity region.

In the first region A, a gate insulating film 22 is provided between the gate electrode 20 and the semiconductor substrate 10. A channel portion 24c is provided in the semiconductor substrate 10 below the gate electrode 20. The channel portion 24c is doped with impurities such as phosphorus, arsenic, boron, or indium (In) to adjust a threshold value of the first transistor Tr1.

In the first region A, a cap insulating film 40 is provided on the gate electrode 20. A first sidewall portion 42 is provided on the side surfaces of the gate electrode 20, the gate insulating film 22, and the cap insulating film 40. A second sidewall portion 44 is provided on the side surface of the first sidewall portion 42 and on a part of the semiconductor substrate 10.

In the first region A, a first stopper film 50, a second stopper film 52, a stress film 56, and a first insulating film 66 are provided so as to cover the gate electrode 20, the cap insulating film 40, the first sidewall portion 42, the second sidewall portion 44, and the semiconductor substrate 10. The gate electrode 20, the gate insulating film 22, the cap insulating film 40, the first sidewall portion 42, and the second sidewall portion 44 are referred to as a first gate structure.

In the second region B, a SiGe film 31 and a gate insulating film 32 are provided between the gate electrode 30 and the semiconductor substrate 10. A channel portion 34c is provided in the semiconductor substrate 10 below the gate electrode 30. The channel portion 34c is doped with impurities such as phosphorus, arsenic, boron, or indium (In) to adjust a threshold value of the second transistor Tr2.

In the second region B, a cap insulating film 40 is provided on the gate electrode 30. A first sidewall portion 42 is provided on the side surfaces of the gate electrode 30, the gate insulating film 32, and the cap insulating film 40. A second sidewall portion 44 is provided on the side surface of the first sidewall portion 42 and on a part of the SiGe film 31 on the semiconductor substrate 10. Fourth sidewalls 48 each having a triangular shape in section and a triangular prismatic shape as a three-dimensional shape are provided on the side surfaces of the second sidewall portion 44. The gate electrode 30, the gate insulating film 32, the cap insulating film 40, the first sidewall portion 42, and the second sidewall portion 44 are referred to as a second gate structure.

In the second region B, the first stopper film 50, the second stopper film 52, and the first insulating film 66 are provided so as to cover the gate electrode 30, the cap insulating film 40, the first sidewall portion 42, the second sidewall portion 44, the fourth sidewalls 48, and the SiGe film 31 on the semiconductor substrate 10.

The gate insulating film 22 and the gate insulating film 32 include, for example, insulators such as silicon nitride (SiON) and hafnium oxide (HfO). The cap insulating film 40 includes, for example, silicon nitride (SiN). The first sidewall portion 42, the second sidewall portion 44, the first stopper film 50, the stress film 56, and the first insulating film 66 include an insulator such as silicon nitride. The second stopper film 52 includes, for example, an insulator such as silicon dioxide. The SiGe film 31 includes silicon germanium (SiGe). A configuration in which the first stopper film 50 and the second stopper film 52 are provided as stopper films in the first region A and the second region B has been described as an example. However, instead of this configuration, a configuration in which only the second stopper film 52 is provided may be used.

In the first region A and the second region B, a second insulating film 68 is provided on the first insulating film 66. The second insulating film 68 includes, for example, an insulating film such as silicon dioxide. Contact plugs 70 and 71 are connected to the source/drain 24 of the first transistor Tr1. Contact plugs 72 and 73 are connected to the source/drain 34 of the second transistor Tr2. The contact plugs 70, 71, 72, and 73 are conductive plugs that penetrate from the upper surface to the lower surface of the second insulating film 68, and connect to the upper surfaces of the source/drain 24 and 34. Wirings 80, 81, 82, and 83 are connected to the upper surfaces of the contact plugs 70, 71, 72, and 73, respectively. The contact plugs 70, 71, 72, and 73 and the wirings 80, 81, 82, and 83 include a conductive material such as tungsten (W).

In the first region A, the stress film 56 covers both sides and above the first gate structure. The stress film 56 has an Omega symbol shape (Ω) in section. The stress film 56 is, for example, a film containing silicon nitride, and includes a material having tensile stress. The stress film 56 applies tensile stress to the channel portion 24c as indicated by an arrow. The stress film 56 is a structure including a tensile stress material.

The first transistor Tr1 in the first region A does not substantially include the fourth sidewall 48. Therefore, the distance between the stress film 56 and the channel portion 24c is shorter, so that the stress film 56 can efficiently apply tensile stress to the channel portion 24c. As a result, the mobility of the first transistor Tr1, that is, the N-channel MOSFET is enhanced, which increases the operating speed of the first transistor Tr1.

In the second region B, the upper and both sides of the second gate structure are not covered by the stress film 56. Therefore, no tensile stress is applied to the channel portion 34c of the second transistor Tr2 by the stress film 56, so that it is possible to restrain decrease of the mobility of the second transistor Tr2, that is, the P-channel MOSFET. Therefore, it is possible to restrain deterioration of the characteristics of the second transistor Tr2.

In the second region B, the fourth sidewalls 48 are provided on both sides of the second gate structure. The first insulating film 66 covering the second transistor Tr2 contains a material that does not easily allow hydrogen to pass therethrough. In a P-channel MOSFET, if a dangling bond at a silicon crystal interface of the channel portion is not sufficiently terminated, the transistor characteristics would deteriorate due to increase of the interface state and decrease of mobility. However, the fourth sidewalls 48 serve as paths through which hydrogen passes during hydrogen heat treatment (hydrogen annealing) for introducing hydrogen into the semiconductor device 1, and therefore the presence of the fourth sidewalls 48 allows sufficient hydrogen to be supplied to the semiconductor substrate 10. Therefore, since the dangling bond at the silicon crystal interface of the channel portion 34c of the second transistor Tr2 can be sufficiently terminated, it is possible to restrain deterioration of the characteristics of the second transistor Tr2, that is, the transistor of the P-channel MOSFET. The fourth sidewalls 48 are structures containing a hydrogen-permeable material.

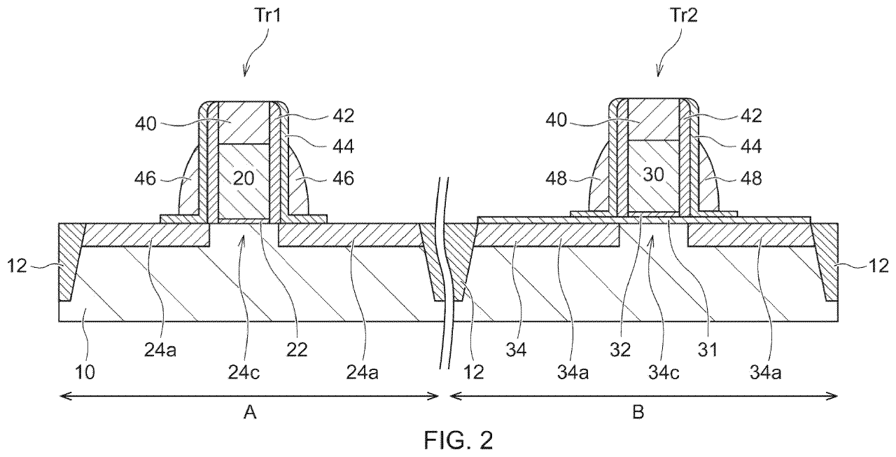

Next, a method for manufacturing the semiconductor device 1 according to the embodiment will be described. First, as shown in FIG. 2, the channel portion 24c, the gate insulating film 22, the gate electrode 20, the cap insulating film 40, the first sidewall portion 42, the second sidewall portion 44, and a third sidewall 46 are formed in the first region A of the semiconductor substrate 10. The low concentration portion 24a is formed in the semiconductor substrate 10. The channel portion 34c, the SiGe film 31, the gate insulating film 32, the gate electrode 30, the cap insulating film 40, the first sidewall portion 42, the second sidewall portion 44, and the third sidewall 46 are formed in the second region B. The low concentration portion 34a is formed in the semiconductor substrate 10. The channel portions 24c, 34c, and the low concentration portions 24a, 34a are formed by performing ion-implantation of chemical species such as phosphorus, arsenic, boron, and indium into the semiconductor substrate 10. The second sidewall portion 44 and the third sidewall 46 can be formed by forming the first sidewall portion 42, forming insulating films that will become the second sidewall portion 44 and the third sidewall 46, and then performing anisotropic dry etching.

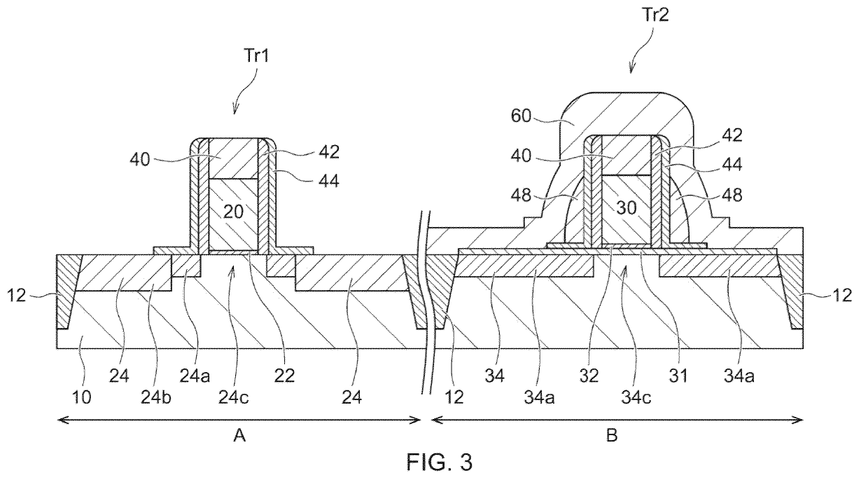

Next, as shown in FIG. 3, photoresist 60 is formed in the second region B. The photoresist 60 is not formed in the first region A. The photoresist 60 is formed by a known lithography technique. Next, etching based on buffered hydrogen fluoride (BHF) is performed using the photoresist 60 as a mask to remove the third sidewall 46 in the first region A. Next, phosphorus or arsenic is ion-implanted into the semiconductor substrate 10 in the first region A by using, as a mask, the photoresist 60 and the gate electrode 20, the cap insulating film 40, the first sidewall portion 42, and the second sidewall portion 44 in the first region A.

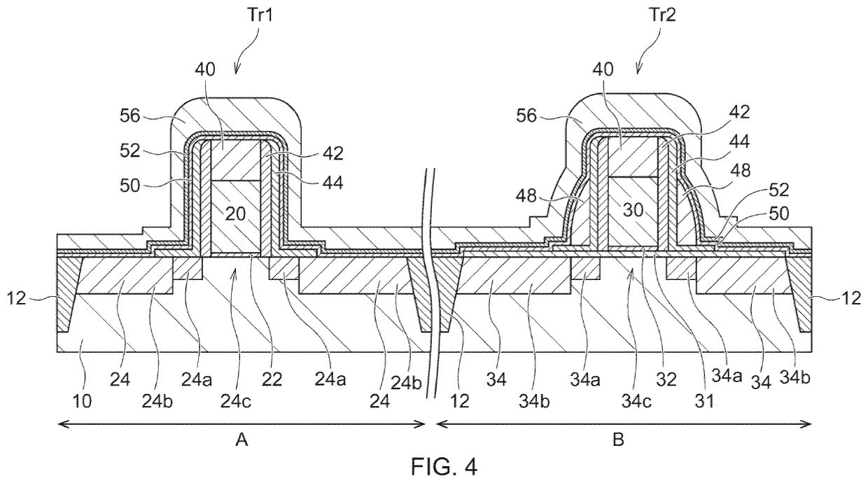

Next, as shown in FIG. 4, after the photoresist 60 is removed, a photoresist (not shown) is formed in the first region A, and boron is ion-implanted into the semiconductor substrate 10 by using, as a mask, the photoresist and the gate electrode 30, the cap insulating film 40, the first sidewall portion 42, the second sidewall portion 44, and the fourth sidewalls 48 in the second region B. The high concentration portion 34b is formed by this ion implantation. Next, after the photoresist is removed, the first stopper film 50, the second stopper film 52, and the stress film 56 are formed on the entire surface of the semiconductor substrate 10. The first stopper film 50 and the stress film 56 contain silicon nitride. The second stopper film 52 contains silicon dioxide. The first stopper film 50, the second stopper film 52, and the stress film 56 are formed by chemical vapor deposition (CVD). Note that only the second stopper film 52 may be formed as a stopper film without forming the first stopper film 50.

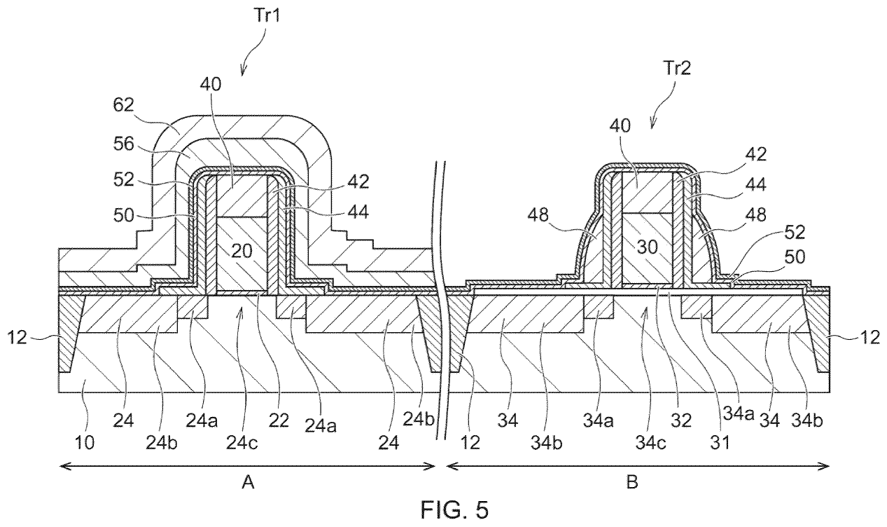

Next, as shown in FIG. 5, photoresist 62 is formed in the first region A. The photoresist 62 is not formed in the second region B. The photoresist 62 is formed by a known lithography technique. Then, the stress film 56 in the second region B is removed by isotropic dry etching using the photoresist 62 as a mask. This dry etching is performed under a condition that the etching rate of the stress film 56 containing silicon nitride is sufficiently higher than the etching rate of the second stopper film 52 containing silicon dioxide. In this dry etching, the etching of the second stopper film 52 is restrained in the second region B, so that it is possible to remove the stress film 56 in the second region B without leaving any part of the stress film 56. The above steps implements a configuration in which the stress film 56 is provided in the first region A and the stress film 56 does not exist in the second region B.

Next, as shown in FIG. 1, after the photoresist 62 is removed, the first insulating film 66 and the second insulating film 68 are formed on the entire surface of the semiconductor substrate 10. The first insulating film 66 contains silicon nitride. The second insulating film 68 contains silicon dioxide. The first insulating film 66 and the second insulating film 68 are formed, for example, by CVD. Next, holes for forming the contact plugs 70, 71, 72, and 73 are formed in the second insulating film 68. The holes are formed by a known lithography technique and anisotropic dry etching. The holes penetrate the second insulating film 68, the first insulating film 66, the stress film 56, the second stopper film 52, the first stopper film 50, and further the SiGe film 31 in the second region B, so that the surfaces of the semiconductor substrate 10 of the source/drain 24 and the source/drain 34 are exposed. Next, tungsten is formed to be embedded in the holes and further cover the upper surface of the second insulating film 68, and then chemical mechanical polishing (CMP) is performed until the tungsten on the upper surface of the second insulating film 68 is removed. The tungsten is formed by CVD. Instead of CMP, an etch-back using anisotropic dry etching may be performed. As a result, the contact plugs 70, 71, 72, and 73 that connect to the source/drain 24 or the source/drain 34 are formed in the holes. Next, tungsten is formed on the second insulating film 68 and the contact plugs 70, 71, 72, and 73, and the tungsten is patterned by a known lithography technique and anisotropic dry etching to form the wirings 80, 81, 82, and 83. Next, the semiconductor device 1 is exposed to a hydrogen atmosphere to be subjected to a hydrogen heat treatment. As a result, the dangling bonds of the silicon atoms are terminated by hydrogen. Through the above steps, the semiconductor device 1 according to the embodiment is formed.

As above, DRAM is described as an example of the semiconductor device according to the embodiment, but the above description is merely one example and not intended to be limited to DRAM. Memory devices other than DRAM, such as static random-access memory (SRAM), flash memory, erasable programmable read-only memory (EPROM), magnetoresistive random-access memory (MRAM), and phase-change memory for example can also be applied as the semiconductor device. Furthermore, devices other than memory, including logic ICs such as a microprocessor and an application-specific integrated circuit (ASIC), for example, are also applicable as the semiconductor device according to the foregoing embodiment.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a substrate;
a first region on the substrate;
a second region on the substrate;
at least one first transistor including a first gate structure provided in the first region;
at least one second transistor including a second gate structure provided in the second region;
triangular prism shaped sidewalls on both sides of the second gate structure; and
a stress film covering over the first gate structure without an intervention of triangular prism shaped sidewalls.

2. The apparatus of claim 1, wherein the triangular prism shaped sidewalls are not provided on both sides of the first gate structure in the first region.

3. The apparatus of claim 1, wherein the first transistor is an N-channel MOSFET.

4. The apparatus of claim 1, wherein the second transistor is a P-channel MOSFET.

5. The apparatus of claim 1, wherein the first gate structure and the second gate structure include gate electrodes over the substrate, respectively.

6. The apparatus of claim 1, wherein the stress film provides a tensile stress to the substrate below the first gate structure.

7. The apparatus of claim 1, wherein the stress film includes silicon nitride.

8. The apparatus of claim 1, wherein the stress film has an Omega symbol shape ((2) at least covering both sides of and above the first gate structure.

9. The apparatus of claim 1, wherein the triangular prism shaped sidewalls include silicon dioxide.

10. An apparatus comprising:
a substrate;
at least one N-channel MOSFET on the substrate including a gate electrode over the substrate and a channel portion below the gate electrode in the substrate;
at least one P-channel MOSFET on the substrate including a gate electrode over the substrate and a channel portion below the gate electrode in the substrate;
a stress film covering over the gate electrode of the N-channel MOSFET; and
triangular prism shaped sidewalls on both sides of the gate electrode of the P-channel MOSFET.

11. The apparatus of claim 10, wherein the gate electrode of the P-channel MOSFET is not covered with the stress film.

12. The apparatus of claim 10, wherein the triangular prism shaped sidewalls are not provided on both sides of the gate electrode of the N-channel MOSFET.

13. The apparatus of claim 10, wherein the stress film provides a tensile stress to the channel portion of the N-channel MOSFET.

14. The apparatus of claim 10, wherein the stress film includes silicon nitride.

15. The apparatus of claim 10, wherein the stress film has an Omega symbol shape (Ω) at least covering both sides and above the gate electrode of the N-channel MOSFET.

16. The apparatus of claim 10, wherein the triangular prism shaped sidewalls include silicon dioxide.

17. An apparatus comprising:
an N-channel MOSFET having a first gate electrode;
a P-channel MOSFET having a second gate electrode;
a first structure covering over an upper portion and both sides of the first gate electrode, the first structure including a tensile stress material; and
a second structure provided on both sides of the second gate electrode, the second structure including a hydrogen permeable material.

18. The apparatus of claim 17, wherein the first structure has an Omega symbol shape (Ω).

19. The apparatus of claim 17, wherein the first structure includes silicon nitride and the second structure includes silicon dioxide.
